(19) United States
(12) Patent Application Publication
(10) Pub. No.: US 2008/0159371 A1
(43) Pub. Date: Jul. 3, 2008

(54) Common mode adaptive equalization

(76) Inventor: Richard Mellitz, Irmo, SC (US)

Correspondence Address: INTEL CORPORATION;c/o INTELLEVATE, LLC, P.O. BOX 52050, MINNEAPOLIS, MN, 55402, US

(21) Appl. No.: 11/646,851

(22) Filed: Dec. 27, 2006

(51) Int. Cl. H03H 7/40

(52) U.S. Cl. 375/232

(57) ABSTRACT

In some embodiments common mode equalization is performed on a received differential signal to produce a voltage signal that is proportional to a common mode voltage of the differential signal. A command signal is provided in response to the common mode equalization to adjust a delay between two pairs of the differential signal. Other embodiments are described and claimed.

### TECHNICAL FIELD

The inventions generally relate to common mode adaptive equalization.

### BACKGROUND

The fabric weave of printed circuit board (PCB) material such as FR4 in relation to how a trace traverses it causes a delay between the wires of a differential channel used for serial differential communication. This delay is caused, for example, because one trace may traverse mostly the fabric peaks, which are made of glass cloth with a dielectric constant of approximately 6, for example, while a second trace may traverse mostly along fabric valleys, which are made mostly of epoxy with a dielectric constant of approximately 3.2, for example. Since the velocity of propagation is roughly proportional to the square root of the dielectric constant, the signals emerging from each side of the pair of signal traces will be delayed with respect to each other. This effect accumulates with distance, so that a 20 inch trace line might have as much as an 80 ps delay, for example. This problem is particularly troublesome when bit periods reach a level below 300 ps, for example. Some proposed methods to combat this dielectric weave problem include rotating Gerber trace routing artwork masters by 10 degrees. However, such methods put the burden of solving the problem on the customer, add further complications to routing procedures, add expense, and are not automated solutions.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a top view of a printed circuit board (PCB) according to some embodiments of the inventions.

FIG. 2 illustrates a cross-sectional view of a PCB according to some embodiments of the inventions.

FIG. 3 illustrates a system according to some embodiments of the inventions.

FIG. 4 illustrates a flow according to some embodiments of the inventions.

FIG. 5 illustrates a graph according to some embodiments of the inventions.

FIG. 6 illustrates a graph according to some embodiments of the inventions.

FIG. 7 illustrates a graph according to some embodiments of the inventions.

FIG. 8 illustrates a graph according to some embodiments of the inventions.

### DETAILED DESCRIPTION

Some embodiments of the inventions relate to common mode adaptive equalization.

In some embodiments common mode equalization is performed on a received differential signal to produce a voltage signal that is proportional to a common mode voltage of the differential signal. A command signal is provided in response to the common mode equalization to adjust a delay between two pairs of the differential signal.

In some embodiments a receiver includes a common mode equalization circuit to perform common mode equalization on a received differential signal to produce a voltage signal that is proportional to a common mode voltage of the differential signal. The receiver also includes a voltage to command converter circuit to provide a command signal to be used to adjust a delay between two pairs of the differential signal in response to the common mode equalization.

In some embodiments a transmitter includes a transmission circuit to transmit a differential signal over a transmission channel, and a delay adjusting circuit to adjust a delay between two pairs of the differential signal in response to a common mode equalization command signal.

In some embodiments a system includes a transmission channel, a differential signal transmitter to transmit a differential signal over the transmission channel, and a differential signal receiver. The receiver includes a common mode equalization circuit to perform common mode equalization on a received differential signal to produce a voltage signal that is proportional to a common mode voltage of the differential signal. The receiver also includes a voltage to command converter circuit to provide a command signal to be used to adjust a delay between two pairs of the differential signal in response to the common mode equalization.

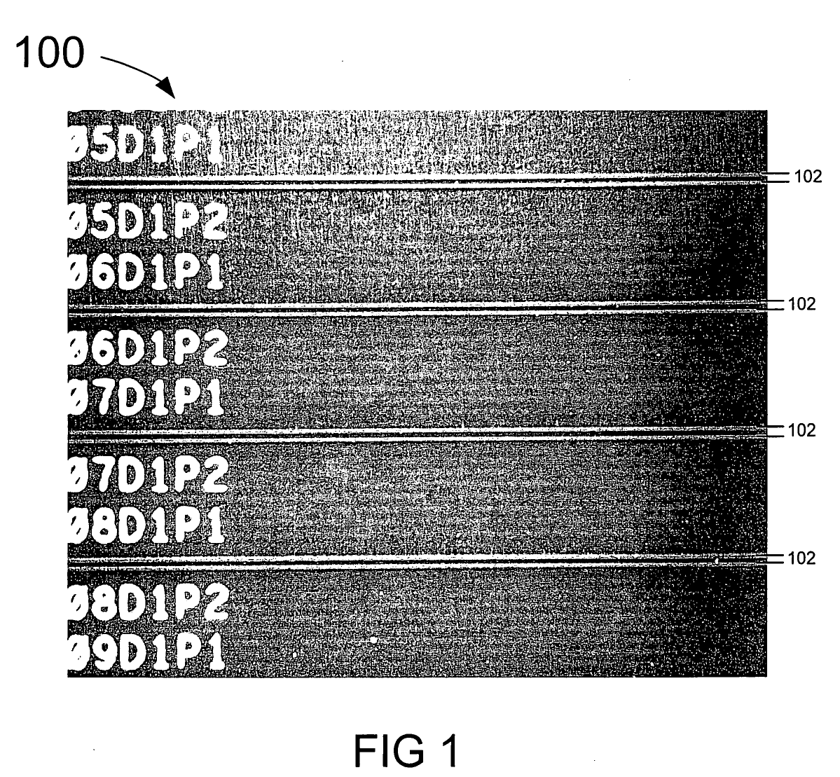

FIG. 1 illustrates a top view of a printed circuit board (PCB) 100 according to some embodiments. PCB 100 is implemented, for example, using a glass cloth weave on FR4 material. PCB 100 includes differential pair traces (transmission lines) 102.

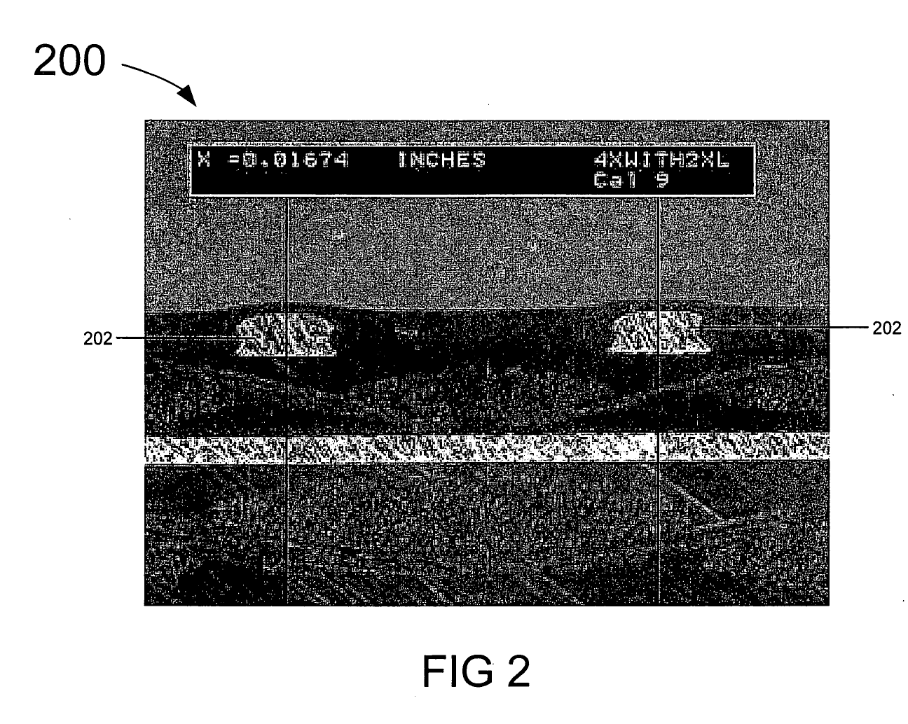

FIG. 2 illustrates a cross-sectional view of a PCB 200 according to some embodiments. PCB 200 is implemented, for example, using a glass cloth weave on FR4 material. PCB 200 includes differential pair traces (transmission lines) 202.

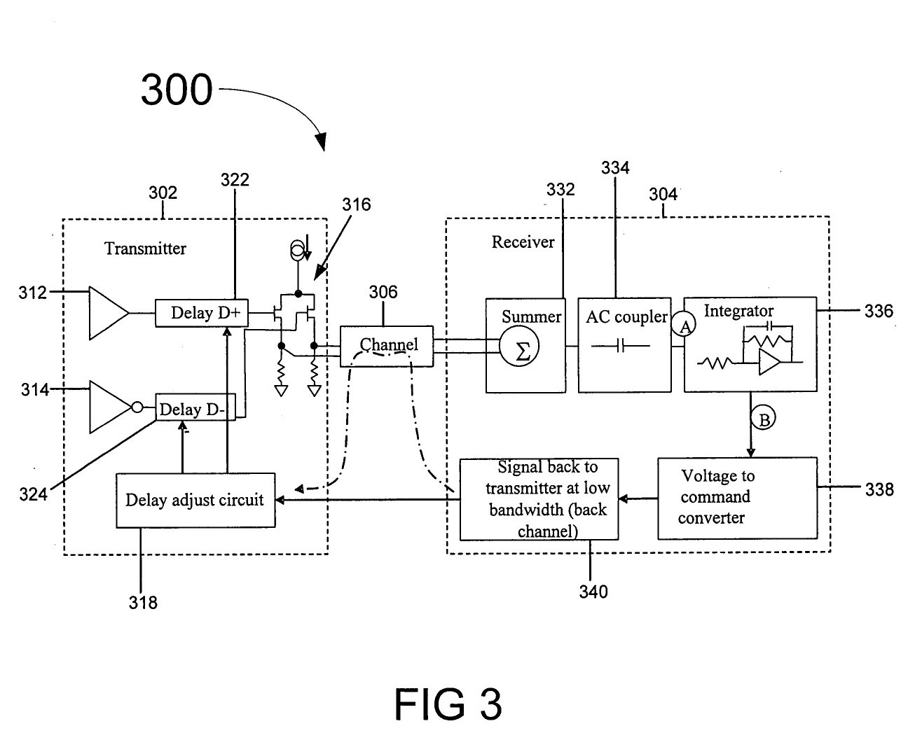

FIG. 3 illustrates a system 300 according to some embodiments. In some embodiments, system 300 includes a transmitter 302, a receiver 304, and a transmission channel 306. In some embodiments transmitter 302 is a differential signal transmitter, receiver 304 is a differential signal receiver, and/or transmission channel 306 is a serial differential transmission channel. In some embodiments a differential signal is injected into the transmission channel 306 from the transmitter 302.

In some embodiments transmitter 302 includes a pre driver 312 (for example, a differential signal driver), a pre driver 314 (for example, a differential signal driver), a current mode differential driver circuit 316, a delay adjustment circuit 318, a positive delay adjustment circuit (Delay D+) 322, and a negative delay adjustment circuit (Delay D−) 324. In some embodiments a current mode differential driver circuit 316 includes two transistors, two resistors, and a current source in the circuit arrangement as illustrated in FIG. 3. However, other circuits may be used in some embodiments.

In some embodiments receiver 304 includes a voltage summing circuit 332, an AC (alternating current) coupler 334, an integrator 336, a voltage to command converter 338, and a circuit 340 to send a signal back to the transmitter 302 (for example, in some embodiment at low bandwidth through a back channel). In some embodiments receiver 304 includes a differential amplifier (not illustrated in FIG. 3) and a voltage summing circuit 332 in addition to the differential amplifier. An output of the voltage summing circuit 332 is AC coupled by AC coupler 334 to provide a signal that is input to integrator 336 (illustrated as signal A in FIG. 3). Integrator 336 is illustrated in FIG. 3 as including, for example, a circuit with an amplifier, two resistors and a capacitor in the arrangement specifically illustrated within box 336 of FIG. 3. However, some embodiments may include different circuits to perform the integration. The output of integrator 336 (illustrated as signal B in FIG. 3) is provided to voltage to command converter circuit 338. In some embodiments, circuit 338 includes, for example, testing if the point B voltage is less than some threshold, and creating a command to increase or decrease a delay between the signals in the drivers of the transmitter 302. In some embodiments circuit 330 is used to send the command signal output by circuit 338 to transmitter 302. In some embodiments, for example, this signal is sent to transmitter 302 along the same link (transmission channel 306), for example, at a sufficiently low frequency to assure receipt at transmitter 302. In this manner, common mode on a serial differential communication channel may be automatically reduced by adaptively adjusting the delay between wires on the differential communication channel with respect to each other. In some embodiments, the AC portion of the common mode is extracted and the result is integrated to produce a voltage level that is proportional to the common mode (for example, voltage B in FIG. 3). This voltage may be used in some embodiments as a feedback mechanism that alters the delay between the differential sides of the transmitter (or in some embodiments between the differential sides of the receiver) so that the integrated AC common mode voltage is below a sufficiently small value.

In some embodiments, everything can be implemented in the receiver. For example, a delay adjustment circuit similar to circuit 318, a positive delay adjustment circuit (Delay D+) similar to circuit 322, and a negative delay adjustment circuit (Delay D−) similar to circuit 324 can be located in the receiver 304 before the voltage summing circuit 332. In such embodiments it is not necessary to transmit a command signal on a channel 306 since signals can be sent through mechanisms internal to the receiver 304.

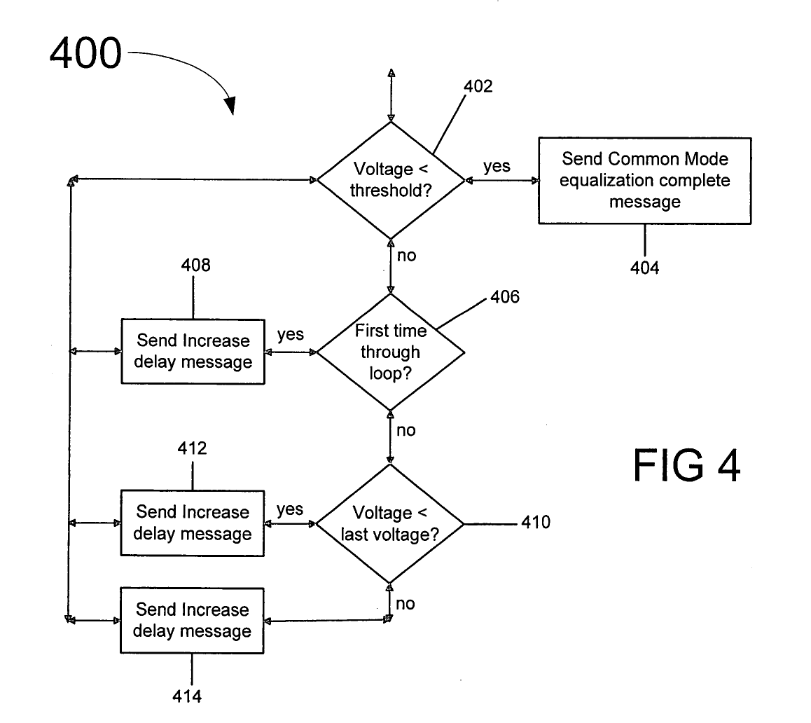

FIG. 4 illustrates a flow 400 according to some embodiments. In some embodiments, for example, flow 400 is provided as the voltage to command converter circuit 338 of FIG. 3. In some embodiments, circuit 338 and/or flow 400 may be implemented in software, hardware, and/or firmware (for example, in some combination of software, hardware, and/or firmware). At 402, a determination is made as to whether a voltage (for example, voltage B illustrated in FIG. 3) is less than a threshold voltage. If the voltage is less than the threshold voltage at 402, then a common mode equalization complete message is sent at 404. If the voltage is not less than the threshold voltage at 402, then a determination is made at 406 as to whether it is a first time through the loop (for example, through box 406). If it is the first time through the loop at 406 then an increase delay message is sent at 408 to increase a delay between transmission drivers, and flow then returns to 402. If it is not the first time through the loop at 406 then flow moves to 410. At 410 a determination is made as to whether the current voltage which is proportional to the common mode voltage is less than the last voltage which was proportional to the common mode voltage prior to the last delay adjustment. If the voltage is less than the last voltage at 410 then an increase delay message to increase the delay between transmission drivers is sent at 412, and flow then returns to 402. If the voltage is not less than the last voltage at 410 then a decrease delay message to decrease the delay between transmission drivers is sent at 414, and flow then returns to 402.

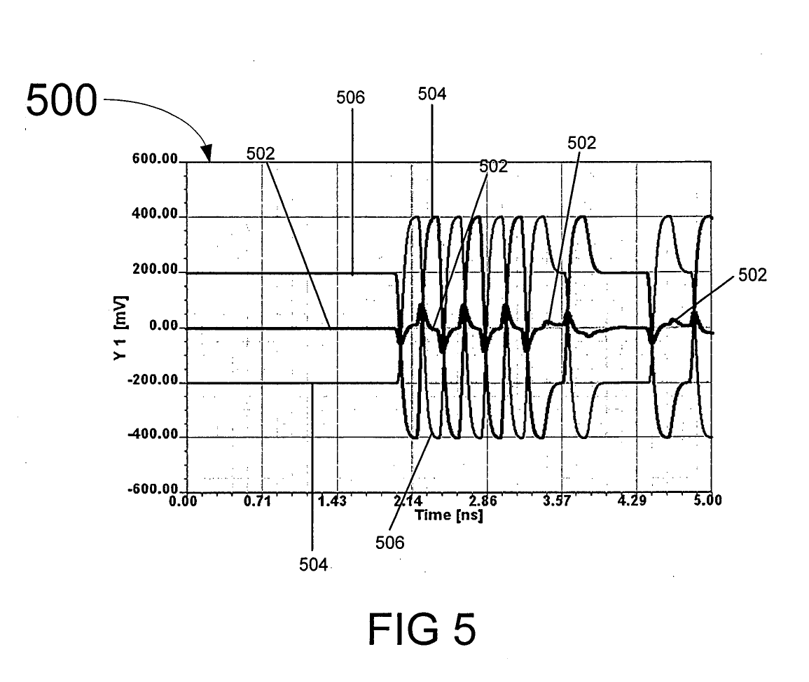

FIG. 5 illustrates a graph 500 according to some embodiments. Graph 500 illustrates a common mode in the differential combined signal 502 resulting from, for example, 10 ps of delay between differential signal 504 and differential signal 506. In FIG. 5 the horizontal axis shows time and the vertical axis shows voltage.

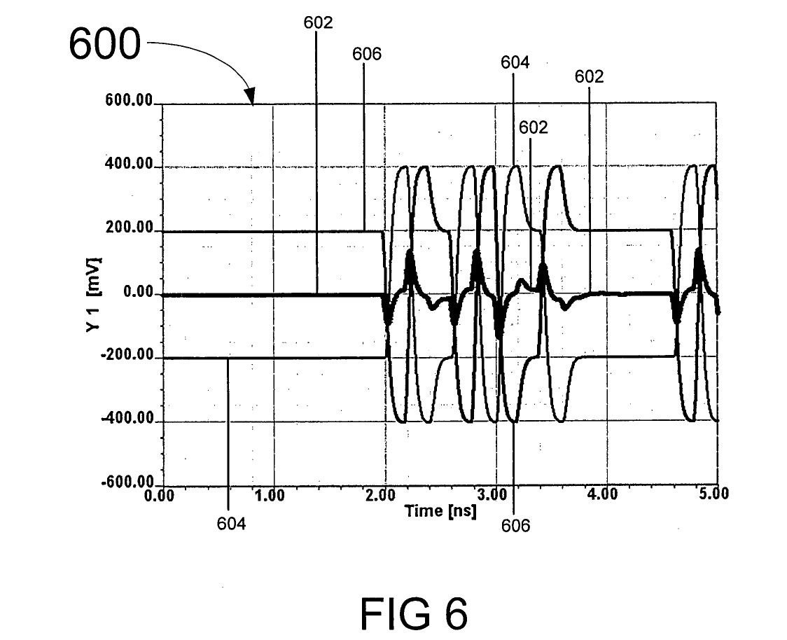

FIG. 6 illustrates a graph 600 according to some embodiments. Graph 600 illustrates a common mode in the differential combined signal 602 resulting from, for example, 25 ps of delay between differential signal 604 and differential signal 606. In FIG. 6 the horizontal axis shows time and the vertical axis shows voltage.

As illustrated in FIG. 5 and FIG. 6, a delay between the wires of a differential pair is manifested at a receiver with an increased high frequency common mode

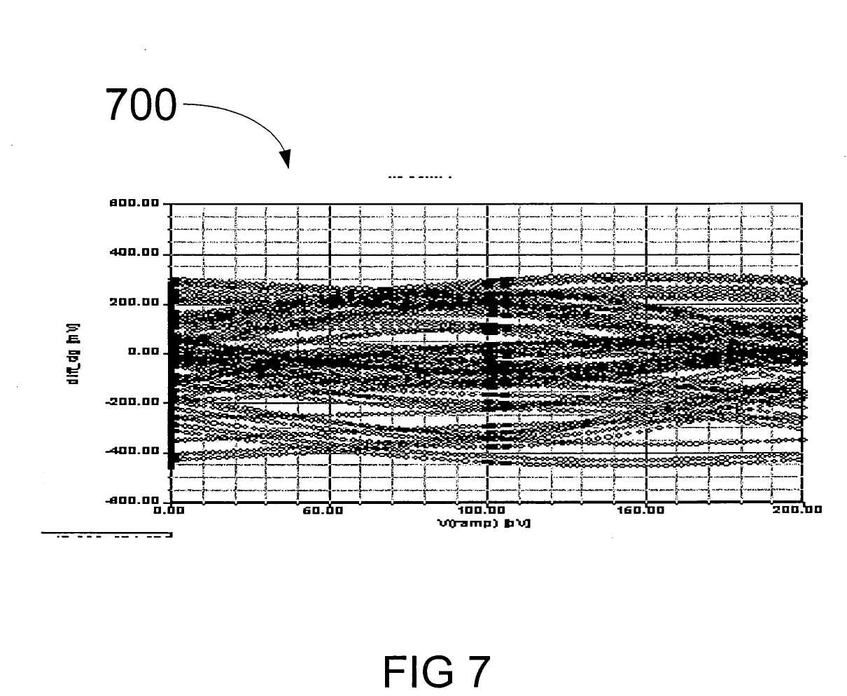

FIG. 7 illustrates a graph 700 of a received differential signal without any common mode equalization (for example, a 5 gigabit per second differential signal through 20 inches of FR4 material with a worst case trace to fiber weave alignment). As apparent from FIG. 7, the differential eye opening (if any) is very difficult to discern. In FIG. 7 the horizontal axis shows bit period folded time and the vertical axis shows voltage.

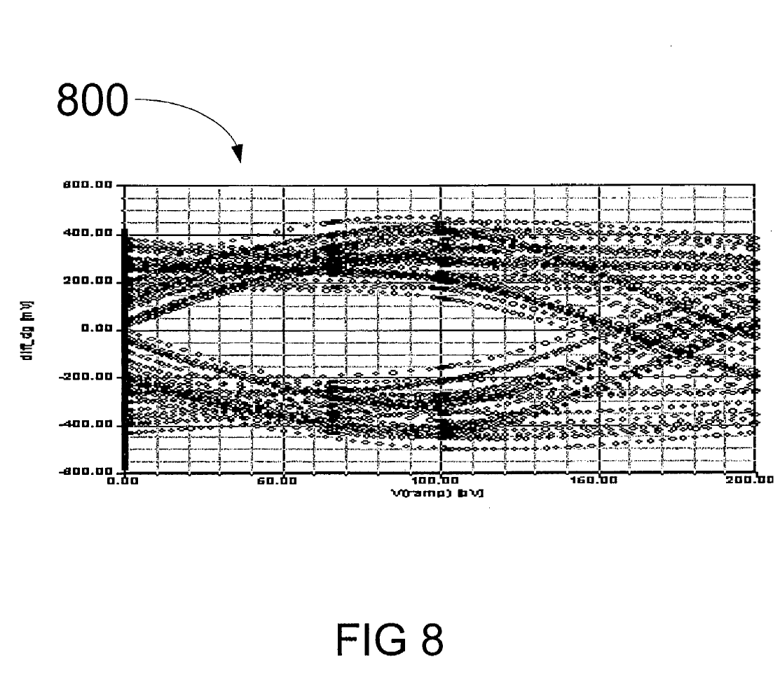

FIG. 8 illustrates a graph 800 of a received differential signal with common mode equalization (for example, a 5 gigabit per second differential signal through 20 inches of FR4 material with a worst case trace to fiber weave alignment). As apparent from FIG. 8, the differential eye opening is easy to discern. As evident from a comparison of FIG. 7 and FIG. 8, common mode equalization greatly improves the differential eye opening. In FIG. 8 the horizontal axis shows bit period folded time and the vertical axis shows voltage.

In some embodiments implementation occurs in a high speed serializer/deserializer (SERDES) (for example, in an Integrated Circuit and/or a transceiver that converts parallel data to serial data and/or serial data to parallel data).

In some embodiments individual control of each half of a differential transmitter is performed. For example, increasing or decreasing of delays between each half may be implemented by individually controlling either one or both of the differential signals.

In some embodiments a low grade material (for example, material such as FR4 material) may be used in conjunction with differential signaling.

In some embodiments common mode equalization is performed at the receiver, a command signal is sent to the transmitter (for example, through a back channel) and a delay between differential signals is adjusted in response to the command signal. However, other embodiments may be implemented. For example, in some embodiments common mode equalization is performed at the receiver and a delay between differential signals is adjusted at the receiver in response to the common mode equalization.

Although some embodiments have been described, according to some embodiments these particular implementations may not be required. Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A method comprising:
performing common mode equalization on a received differential signal to produce a voltage signal that is proportional to a common mode voltage of the differential signal; and
providing a command signal to be used to adjust a delay between two pairs of the differential signal in response to the common mode equalization.

2. The method of claim 1, wherein the performing common mode equalization includes AC coupling the received differential signal and then integrating the AC coupled signal.

3. The method of claim 1, further comprising transmitting the command signal to a transmitter.

4. The method of claim 3, wherein the transmitting is at a low bandwidth and is transmitted on a same transmission channel as the received differential signal.

5. The method of claim 1, further comprising adjusting the delay between the two pairs in response to the command signal.

6. A receiver comprising:
a common mode equalization circuit to perform common mode equalization on a received differential signal to produce a voltage signal that is proportional to a common mode voltage of the differential signal; and
a voltage to command converter circuit to provide a command signal to be used to adjust a delay between two pairs of the differential signal in response to the common mode equalization.

7. The receiver of claim 6, wherein the common mode equalization circuit includes an AC coupler to AC couple the received differential signal and also includes an integrator to integrate the AC coupled signal.

8. The receiver of claim 6, further comprising a back channel transmitter to transmit the command signal to a transmitter.

9. The receiver of claim 8, wherein the back channel transmitter transmits the command signal at a low bandwidth to a same transmission channel as the received differential signal.

10. The receiver of claim 6, further comprising a delay adjusting circuit to adjust the delay between the two pairs in response to the command signal.

11. A transmitter comprising:
a transmission circuit to transmit a differential signal over a transmission channel; and
a delay adjusting circuit to adjust a delay between two pairs of the differential signal in response to a common mode equalization command signal.

12. The transmitter of claim 11, wherein the transmitter receives the common mode equalization command signal from a back channel of the transmission channel.

13. The transmitter of claim 11, wherein the delay adjusting circuit is to adjust the delay between the two pairs using independent control of transmission of each of the two pairs.

14. The transmitter of claim 11, further comprising a positive delay adjusting circuit and a negative delay adjusting circuit, wherein the delay adjusting circuit is to control the positive delay adjusting circuit and the negative delay adjusting circuit to adjust the delay between the two pairs.

15. A system comprising:
a transmission channel;
a differential signal transmitter to transmit a differential signal over the transmission channel; and
a differential signal receiver comprising:
a common mode equalization circuit to perform common mode equalization on a received differential signal to produce a voltage signal that is proportional to a common mode voltage of the differential signal; and
a voltage to command converter circuit to provide a command signal to be used to adjust a delay between two pairs of the differential signal in response to the common mode equalization.

16. The system of claim 15, wherein the common mode equalization circuit includes an AC coupler to AC couple the received differential signal and also includes an integrator to integrate the AC coupled signal.

17. The system of claim 15, the receiver further comprising a back channel transmitter to transmit the command signal to the transmitter.

18. The system of claim 17, wherein the back channel transmitter transmits the command signal at a low bandwidth over the transmission channel.

19. The system of claim 15, the receiver further comprising a delay adjusting circuit to adjust the delay between the two pairs in response to the command signal.

20. The system of claim 15, the transmitter including a delay adjusting circuit to adjust a delay between two pairs of the differential signal in response to the command signal.

21. The system of claim 20, wherein the delay adjusting circuit is to adjust the delay between the two pairs using independent control of transmission of each of the two pairs.
